(19) United States
(12) Patent Application Publication
(10) Pub. No.: US 2026/0352164 A1
(43) Pub. Date: Nov. 5, 2026

(54) A METHOD AND APPARATUS FOR DETERMINING VALUES OF CONFIGURATION PARAMETERS FOR A DIGITIAL FRONT END

(71) Applicant: Telefonaktiebolaget LM Ericsson (publ), Stockholm (SE)

(72) Inventors: Simone GRIMALDI, Staffanstorp (SE); Gustav OLSSON, Växjö (SE); Mohamed HAMID, Malmö (SE); Hans HAGBERG, Limhamn (SE)

(21) Appl. No.: 19/487,250

(22) PCT Filed: May 24, 2024
(86) PCT No.: PCT/EP2024/064404

§ 371 Date: Nov. 24, 2025

Related U.S. Application Data
(60) Provisional application No. 63/504,526, filed on May 26, 2023.

(51) Int. Cl. H03F 1/32

(52) U.S. Cl. CPC H03F 1/3247

(57) ABSTRACT

Embodiments described herein relate to methods and apparatuses for optimizing a digital front end, DFE, wherein the DFE is configured to perform a plurality of functions, to generate a digital output signal, y[n], from a digital input signal, x[n], wherein the digital output signal y[n] is for input into an analog front end, AFE. A method performed by an optimizer includes applying an optimization process to a first objective function to determine first values for a responsive plurality of sets of first configuration parameters for the plurality of functions, wherein the first objective function includes a first component derived from a set, S, of signal parameters, representative of the digital output signal y[n] and/or of one or more analog signals measured at a point within and/or at an output of the AFE, wherein the set of signal parameters is dependent on the plurality of sets, P₁ . . . . P_{M}, of first configuration parameters; and initiating configuration of the DFE with the first values of the plurality of sets of first configuration parameters.

### TECHNICAL FIELD

Embodiments described herein relate to methods and apparatuses for a digital front end, DFE, wherein the DFE is configured to perform a plurality of functions, to generate a digital output signal, y[n], from a digital input signal, x[n]. The methods and apparatuses are for determining values of a respective plurality of sets, P₁ . . . . P_{M}, of first configuration parameters, for the plurality of functions.

### BACKGROUND

The digital front end (DFE) is a key block of modern radio base stations which performs essential operations such as the digital correction analog impairments introduced by the analog front-end (AFE). A notable example of such impairments is the nonlinearity introduced by the radio-frequency (RF) power amplifiers (PAS). The DFE may comprise a number of digital blocks, and its structure may be different depending on the specific application.

Nevertheless, a common configuration for DFE might include a combination of blocks performing:
Crest-factor reduction (CFR), which reduces the peak-to-average power ratio (PAPR) of the signal to facilitate the digital linearization of the AFE.
Digital hard-limiting, which can be used to safeguard the PA by clipping peaks escaping the CFR and peaks generated when oversampling to DPD rate.
Digital pre-distortion (DPD), which takes care of pre-distorting the digital signal to compensate for the nonlinearity of the PA.
Up-/down-samplers: which adapt the sample-rate of the digital signal.
Digital filters: which might be included within the above-mentioned blocks and in standalone fashion.

As the role of DFE blocks is to mitigate hardware impairments, a common approach to their design and configuration is to arbitrarily and sub-optimally partition the contribution to relevant performance metrics (e.g., adjacent channel leakage ratio (ACLR) and error-vector magnitude (EVM) (see 3GPP TS 38.104 version 15.14.0)) among the digital blocks to achieve a compromise between complexity and performance given target requirements and specifications.

However, the complexity of some of the above blocks might be considerably high, particularly with respect to the number of parameters to tune in the radio design process. This complexity might escalate to the point that even standalone configuration of parameters for a single block might become very complex and require case-by case configuration of several parameters, which is often use-case specific.

Other than extremely specialized literature on DPD and CFR, a disclosure that investigates joint design of CFR and DPD blocks is given in S Wang, M. Roger and C. Lelandais-Perrault, “Impacts of Crest Factor Reduction and Digital Predistortion on Linearity and Power Efficiency of Power Amplifiers,” in IEEE Transactions on Circuits and Systems II: Express Briefs, vol. 66, no. 3, pp. 407-411, March 2019, doi: 10.1109/TCSII.2018.2855084. Nevertheless, the available literature on joint CFR and DPD has the following gaps:
1. It ignores that in real-world DFEs other blocks are used, which might compromise, or at least alter, the effectiveness of the optimization if not considered; an example are the hard-clipping stages which might be included at different points of the DFE, up-samplers used to adapt sample-rate of the signal at different point in the chain, as well as digital filters within and/or outside the CFR and DPD blocks.
2. It proposes optimizations designed for a specific combinations of DPD and CFR algorithms, which de facto limits the flexibility in DFE design.

In prior solutions the joint configuration of the blocks is often overlooked or overly simplified due to the above-mentioned complexity, and a block-by-block sub-optimal parameter selection is often favoured for simplicity, given target requirements on complexity and output signal properties (such as the above-mentioned EVM and ACLR).

### SUMMARY

According to some embodiments there is provided a method performed by an optimizer for a digital front end, DFE, wherein the DFE is configured to perform a plurality of functions, to generate a digital output signal, y[n], from a digital input signal, x[n], and wherein the method is for determining values P₁* . . . . P_{M}* for a respective plurality of sets, P₁ . . . . P_{N}, of first configuration parameters, for the plurality of functions, wherein the digital output signal y[n] is for input into an analog front end, AFE. The method comprises applying an optimization process to a first objective function to determine values for the plurality of set of first configuration parameters, wherein the first objective function comprises a first component derived from a set, S, of signal parameters, representative of the digital output signal y[n] and/or of one or more analog signals measured at a point within and/or at an output of the AFE, wherein the set of signal parameters is dependent on the plurality of sets, P1 . . . . P_{M}, of first configuration parameters; and initiating configuration of the DFE with the plurality of sets of first configuration parameters.

According to some embodiments there is provided an optimizer for a digital front end, DFE, wherein the DFE is configured to perform a plurality of functions, to generate a digital output signal, y[n], from a digital input signal, x[n], and wherein the optimizer is for determining values, P₁* . . . . P_{M}*, of a respective plurality of sets, P₁ . . . . P_{M}, of first configuration parameters, for the plurality of functions, wherein the digital output signal y[n] is for input into an analog front end, AFE. The optimizer comprises processing circuitry and a memory, the memory containing instructions executable by the processing circuitry whereby the optimizer is operable to: apply an optimization process to a first objective function to determine values for the plurality of set of first configuration parameters, wherein the first objective function comprises a first component derived from a set, S, of signal parameters, representative of the digital output signal y[n] and/or of one or more analog signals measured at a point within and/or at an output of the AFE, wherein the set of signal parameters is dependent on the plurality of sets, P₁ . . . . P_{M}, of first configuration parameters; and initiate configuration of the DFE with the first values of plurality of sets of first configuration parameters.

According to some embodiments there is provided a system comprising an optimizer as described above, and the DFE.

According to some embodiments there is provided base station comprising a system as described above.

According to some embodiments there is provided computer program, comprising instructions which, when executed on at least one processor, cause the at least one processor to carry out a method as described above.

According to some embodiments there is provided carrier containing the computer program according as described above, wherein the carrier comprises one of an electronic signal, optical signal, radio signal or computer readable storage medium.

According to some embodiments there is provided computer-readable medium comprising instructions that, when executed on at least one processor, cause the at least one processor to perform the method as described above.

According to some embodiments there is provided computer program product comprising non transitory computer readable media having stored thereon a computer program as described above.

Aspects and examples of the present disclosure thus provide a holistic optimization scheme covering the entire digital front end (DFE) without setting requirements on the selection of the processes in the specific blocks, and where the optimization is performed 1) in offline mode and/or, 2) online (e.g. at runtime). The optimization generates values for sets of first configuration parameters for an arbitrary number of DFE blocks which can be used to 1) aid design of blocks, 2) re-configure blocks at run time, and/or 3) adapt DFE blocks at run-time.

The optimization(s) is based on the solution of an arbitrarily constrained optimization problem(s) allowing for generating configurations that ensure optimization (e.g., minimization) of an objective function (including one or more of estimated computational complexity of the DFE, and signal parameters) while satisfying a set of constraints (for example comprising one or more of estimated computational complexity of the DFE, and signal parameters).

### BRIEF DESCRIPTION OF THE DRAWINGS

For a better understanding of the embodiments of the present disclosure, and to show how it may be put into effect, reference will now be made, by way of example only, to the accompanying drawings, in which:

FIG. 1 illustrates a system 100 comprising a digital front end (DFE) and an analog front end (AFE).

FIG. 2 illustrates a method performed by an optimizer for a digital front end;

FIG. 3 illustrates an example of a DFE that may be configured by an optimizer 301 implementing the method of FIG. 2;

FIG. 4 is a table illustrating an example of grid-search results for an optimization of the DFE illustrated in FIG. 3;

FIG. 5 illustrates ACLR at the PA output (of FIG. 3) when varying the nonlinear order of the DPD and clipping ratio of CFR block.

FIG. 6 illustrates the EVM at PA output (of FIG. 3) when varying nonlinear order of the DPD and clipping ratio of CFR block.

FIG. 7 illustrates PAPR at PA input (of FIG. 3) when varying nonlinear order of the DPD and clipping ratio of CFR block;

FIG. 8 illustrates an optimizer comprising processing circuitry (or logic);

FIG. 9 is a block diagram illustrating an optimizer according to some embodiments;

FIG. 10 illustrates a base station comprising a DFE;

FIG. 11 illustrates a network comprising a base station;

FIG. 12 is a table illustrating an example of search space information, R, (e.g. grid-search results for an optimization of the DFE illustrated in FIG. 3)

FIG. 13 is a graph illustrating an example the values of the first objective function for the entries of the search space information R.

### DETAILED DESCRIPTION

Generally, all terms used herein are to be interpreted according to their ordinary meaning in the relevant technical field, unless a different meaning is clearly given and/or is implied from the context in which it is used. All references to a/an/the element, apparatus, component, means, step, etc. are to be interpreted openly as referring to at least one instance of the element, apparatus, component, means, step, etc., unless explicitly stated otherwise. The steps of any methods disclosed herein do not have to be performed in the exact order disclosed, unless a step is explicitly described as following or preceding another step and/or where it is implicit that a step must follow or precede another step. Any feature of any of the embodiments disclosed herein may be applied to any other embodiment, wherever appropriate. Likewise, any advantage of any of the embodiments may apply to any other embodiments, and vice versa. Other objectives, features and advantages of the enclosed embodiments will be apparent from the following description.

The following sets forth specific details, such as particular embodiments or examples for purposes of explanation and not limitation. It will be appreciated by one skilled in the art that other examples may be employed apart from these specific details. In some instances, detailed descriptions of well-known methods, nodes, interfaces, circuits, and devices are omitted so as not obscure the description with unnecessary detail. Those skilled in the art will appreciate that the functions described may be implemented in one or more nodes using hardware circuitry (e.g., analog and/or discrete logic gates interconnected to perform a specialized function, ASICs, PLAs, etc.) and/or using software programs and data in conjunction with one or more digital microprocessors or general purpose computers. Nodes that communicate using the air interface also have suitable radio communications circuitry. Moreover, where appropriate the technology can additionally be considered to be embodied entirely within any form of computer-readable memory, such as (ROM, EEPROM, Flash memory, a memory disc, RAM etc.) solid-state memory, magnetic disk, or optical disk containing an appropriate set of computer instructions that would cause a processor to carry out the techniques described herein.

Hardware implementation may include or encompass, without limitation, digital signal processor (DSP) hardware, a reduced instruction set processor, hardware (e.g., digital or analogue) circuitry including but not limited to application specific integrated circuit(s) (ASIC) and/or field programmable gate array(s) (FPGA(s)), and (where appropriate) state machines capable of performing such functions.

Certain aspects of the present disclosure and their embodiments may provide solutions to these or other challenges. The steps of any methods disclosed herein do not have to be performed in the exact order disclosed, unless a step is explicitly described as following or preceding another step and/or where it is implicit that a step must follow or precede another step.

Particular embodiments are described more fully with reference to the accompanying drawings. Other embodiments, however, are contained within the scope of the subject matter disclosed herein. The disclosed subject matter should not be construed as limited to only the embodiments set forth herein; rather, these embodiments are provided by way of example to convey the scope of the subject matter to those skilled in the art.

Embodiments described herein provide a joint optimization scheme covering a plurality of the functions of the digital front end (DFE) where the optimization is performed 1) offline and/or, 2) at runtime.

The optimization generates sets of configuration parameters for an arbitrary number of DFE functional blocks. The optimization may be based on a constrained minimization of a first objective function. The first objective function may be composed of a combination of an estimated cost (e.g., a computation cost such as estimated floating point operations per second (FLOPS) and/or a power consumption cost), and a set of signal parameters representative of an output signal of the DFE and/or of one or more analog signals measured at a point within and/or at an output of the AFE. The set of signal parameters may for example be determined based on one or more feedback signals received from arbitrary points in the signal chain (e.g. in the DFE or the AFE including the output of the AFE and/or DFE) (e.g., error vector magnitude (EVM), adjacent channel-leakage ratio (ACLR) measured at the PA output, peak-envelope power (PEP) and RMS power measured at the PA input).

The configuration parameters optimized in offline mode may be used to design, configure, and/or reconfigure the DFE. They may be, in practice, used to:
Aid the co-design and joint configuration of DFE blocks.
Re-configure the chain over a long-time horizon in an open-loop fashion (e.g., determine the specific sets of parameters for a different operational mode of the base station).

The configuration parameters optimized in the runtime mode may instead not be related to the design of DFE blocks but may encompass block configuration-related parameters that can be adapted over a short time-horizon (e.g., the coefficients of the DPD model together with the threshold level of the hard-limiter). The optimization of such parameters also allows for a joint-optimization strategy, as described for offline mode.

In practice, the configuration parameters optimized at runtime (e.g. online) may be, but are not limited to, a subset of the configuration parameters that can be optimized offline. The runtime optimization may be guided by a previously conducted offline optimization. For example, the runtime optimization may use the online optimizer to provide incremental solutions based on sets of initial configuration parameters determined via offline optimization, or using parameters optimized offline as a fallback configuration.

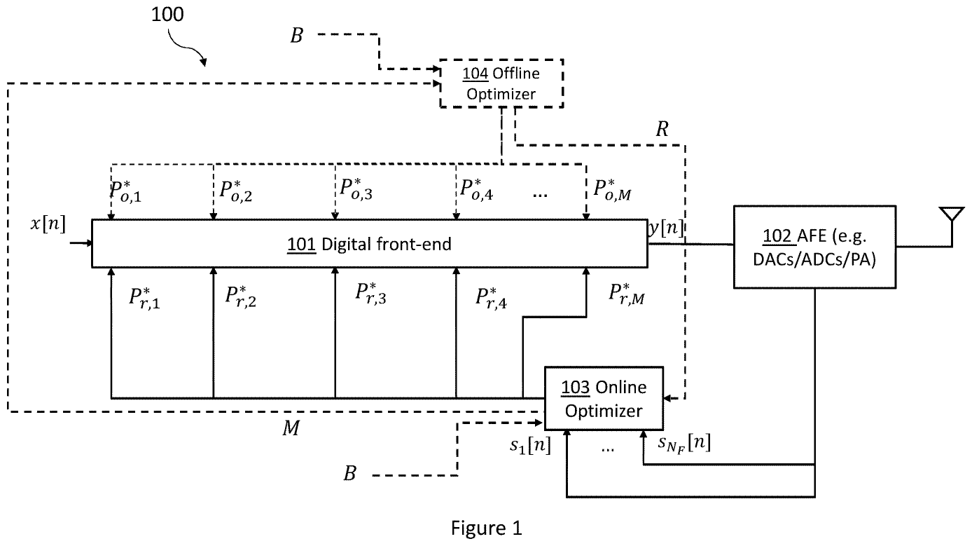

FIG. 1 illustrates a system 100 comprising a digital front end (DFE) 101 and an analog front end (AFE) 102.

The DFE 101 receives an input digital signal x[n] and performs a plurality of functions, on the input digital signal x[n] to generate the digital output signal y[n]. The digital output signal y[n] is provided to the AFE 102. The AFE may comprise for example a power amplifier. The AFE 102 may interface with the DFE 101 via a Digital-to-Analog convertor.

The plurality of functions may comprise one or more of: crest-factor reduction, digital hard-limiting, digital pre-distortion, up-sampling or down-sampling, and digital filtering.

Each of the plurality of functions, Fᵢ, may be configured by a set of first configuration parameters, Pᵢ. As an example, an up-sampling function may be configured by the following first configuration parameters: up-sampling ratio, length of the finite-impulse response (FIR) filters used in the resampling process, and coefficients of the FIR filters.

The system 100 further comprises an optimizer. The optimizer may be an online (e.g. runtime) optimizer 103 or an offline optimizer 104. The online optimizer may be utilised when the DFE is actually being used to transmit a signal to the AFE. The offline optimizer may be used when the DFE is not being used to transmit a signal to the AFE. The offline optimizer may utilise a simulated DFE and/or a simulated AFE (of arbitrary accuracy) to conduct the offline optimizations. Although the offline optimizer 104 and the online optimizer 103 are illustrated in separate blocks in FIG. 1, it will be appreciated that they may in some examples be implemented by a single logical entity.

The optimizer may be configured to provide values

$${P}_{1}^{*} to {P}_{M}^{*}$$

(e.g.

$${P}_{o , 1}^{*} to {P}_{o , M}^{*}$$

for the offline optimizer 104 or

$${P}_{r , 1}^{*} to {P}_{r , M}^{*}$$

for the online optimizer 103) for the sets of first configuration parameters to the DFE to configure the plurality of functions. It will be appreciated that herein the term “value” may be used to encompass a quantitative of qualitative value for a configuration parameter.

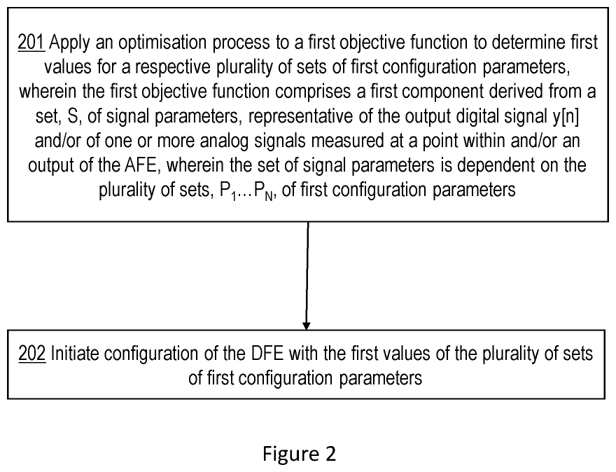

FIG. 2 illustrates a method performed by an optimizer for a digital front end, DFE. The DFE is configured to perform a plurality of functions, to generate a digital output signal, y[n], from a digital input signal, x[n]. The method may be for determining first values for a respective plurality of sets, P₁ . . . . P_{M}, of first configuration parameters, for the plurality of functions. The digital output signal y[n] is for input into an analog front end, AFE.

The method of FIG. 2 may be considered to implement, for example, a constrained, optimization procedure to generate the values,

$${P}_{1}^{*} to {P}_{M}^{*}$$

for the sets of first configuration parameters which configure the M DFE functions (e.g. functional blocks or sub-blocks of the DFE), where M is an integer number indicating the number of functions of the DFE that are being involved in the optimization process. It will be appreciated that the DFE may be performing more functions that those that are being optimized.

It will be appreciated that each function of the DFE, Fᵢ that is involved in the optimization is configured by a respective set of configuration parameters, Pᵢ. However, the set of first configuration parameters Pᵢ may not comprise all possible configuration parameters of the function Fᵢ. The set of first configuration parameters Pᵢ are those first configuration parameters that are being optimized by the optimizer.

The method of FIG. 2 may be performed by an online optimizer 103 and/or an offline optimizer 104. The optimizer (either offline or online) may be comprised within a base station. In some examples, the optimizer (either offline or online) may be hosted elsewhere.

In step 201 the method comprises applying an optimization process to a first objective function to determine values,

$${P}_{1}^{*} … {P}_{M}^{*} ,$$

for the plurality of sets of first configuration parameters, wherein the first objective function comprises a first component derived from a set, S, of signal parameters, representative of the digital output signal y[n] and/or of one or more analog signals measured at a point within and/or at an output of the AFE, wherein the set of signal parameters is dependent on the plurality of sets, P₁ . . . . P_{M}, of first configuration parameters.

Each of the sets of first configuration parameters P₁ to P_{M} may comprise:
one or more single parameters (e.g., a threshold setting) and/or one or more vector parameters (e.g., a set of coefficients for a filter).

Returning to the example for the up-sampler, the optimization process may return the values:
Pₙ*=[X, Y taps, Z] where X is an value, Y is an integer, and Z is a vector of values for the coefficients of the FIR filters,
   that correspond to the set of first configuration parameters:
Pₙ=[up-sampling ratio, length of the finite-impulse response (FIR) filters used in the resampling process, and coefficients of the FIR filters]

It will be appreciated that step 201 may result in values for each of the sets of first configuration parameters P₁ . . . . P_{M}.

It will be appreciated that each signal parameter S₁ to S_{L} in the set, S, of signal parameters may be dependent on the plurality of sets of first configuration parameters.

In other words, S=[S₁ . . . . S_{L}] where Sᵢ=sᵢ(P₁ . . . . P_{N}), where sᵢ is an unknown function.

It will however be appreciated that not all signal parameters will be affected by all of the sets of first configuration parameters.

The set of signal parameters may comprise one or more of: error vector magnitude, EVM, adjacent channel leakage ratio, ACLR, peak-envelope power, PEP, and root mean squared, RMS, power.

In examples where the method of FIG. 2 is being performed offline, for example by offline optimizer 104, the set of signal parameters may be determined utilising a simulated DFE chain. For example, the set of signal parameters may be determined utilising one or more of a simulated DFE and/or simulated AFE (of arbitrary accuracy). The simulated DFE and AFE may be utilised to estimate the response of the AFE+DFE (i.e., determine signal parameters S=[S1, . . . . S_{L}]) with respect to different configurations of the parameter sets P₁ . . . . P_{M}.

In examples in which the method of FIG. 2 is being performed online, for example, by online optimizer 103, the set of signal parameters may be determined from one or more of: the digital output signal y[n], one or more feedback signals, s₁[n] derived from one or more analog signals measured at a point within and/or at an output of the AFE, and a feedback signal derived from any point inside the AFE (e.g. a signal output from a PA).

In applying the optimization process it will be appreciated that a global or local optima for the values of the sets of first configuration parameters may be reached. However, in some cases the values of the sets of first configuration parameters may be in some way improved or better values will be chosen than may have been previously possible, for example, by applying an optimization process to the parameters of each function individually. It will be appreciated that in the application of the optimization process a stopping criterion may be introduced which prevents the optimization process from reaching a global or local maxima. Nonetheless the application of the optimization process may still lead to an improved selection of the values of the sets of first configuration parameters.

In some examples applying the optimization process may comprise minimising the first objective function.

In some examples, the optimization process comprises a grid-search process over possible values for the sets of first configuration parameters to find values for the sets of first configuration parameters that minimizes the first objective function. The optimization process may in some examples comprise mixed-integer programming (e.g. linear or quadratic). It will be appreciated that other possible optimization processes are possible, for example utilising machine learning.

In some examples, the first component of the first objective function may comprise a weighted sum of the set of signal parameters.

In some examples, the first component is further derived from a set, B, of baseband parameters. For example, the set B may comprise one or more of: a number of baseband carriers, one or more frequencies of baseband carriers, one or more bandwidths of baseband signals, one or more modulation and coding schemes of carriers and a power of one or more carriers. It will be appreciated that the set B of baseband parameters may be received form a baseband block and may be utilised during both online and/or offline optimization (as will be described in more detail below.

In some examples, the first objective function comprises a second component derived from one or more costs (e.g. computations costs or power consumption costs). The second component may be derived from respective computational costs, C₁ . . . . C_{M}, associated with the plurality of functions. The computational costs, C₁ . . . . C_{M}, may be dependent on the plurality of sets of first configuration parameters, P₁ . . . . P_{M}. In some examples, each of the computational costs is dependent on the respective set of first configuration parameters for the associated function. For example, Cᵢ=cᵢ(Pᵢ), where cᵢ is an function. The computational costs for the plurality of functions may be represented by a vector C=[C₁ . . . . C_{M}]

Where the optimization process comprises a minimisation, the optimization process may be expressed as follows:

$${minimize}_{{P}_{1} , … , {P}_{M}}$$

ƒ₁(S, C), where ƒ₁(S, C) comprises the first objective function.

It will be appreciated that ƒ₁(S, C) may comprise a linear or nonlinear combination of the first component and the second component.

In some examples, the optimization process is subject to one or more constraints.

For example, the one or more constraints may comprise one or more limits on values of the set of signal parameters. Additionally or alternatively, the one or more constraints may comprises one or more limits on values of the computational costs. In some examples, the one or more constraints comprise limits on combinations of C and S.

For example, the optimization problem may be subject to constraints as follows:

$${P}_{o , 1}^{*} , … , {P}_{o , M}^{*}$$

Where “Limit #n on arbitrary combination of {C, S}” is an arbitrary limit (e.g. upper-limit, lower-limit or both) on a combination of one or more of the elements of the signal parameters vector S and of the estimated computational complexity vector C.

Consider an example where the method of FIG. 2 is being performed online. In this example, the sets of first configuration parameters may be considered runtime parameters and may be expressed as: P_{r,1}, . . . ,P_{r,M}. The method of FIG. 2 in this example may comprise obtaining a respective plurality of sets of initial values,

$${P}_{r}^{*}$$

for initial configuration parameters P_{o,1}, . . . ,P_{o,M} of the plurality of functions.

The initial values may be received from an offline optimizer (e.g. as illustrated in FIG. 1). However, in some examples the offline optimization may have been performed by the same optimizer that performs the online optimization. The sets of first configuration parameters P_{r,1}, . . . ,P_{r,M} may not be the same as the initial configuration parameters P_{o,1}, . . . , P_{o,M}, but there may be some overlap. For example, in set P_{r,1} may be different to the set P_{o,1} but they may both comprise the parameter p_{1,1}.

The values of the initial configuration parameters may have been previously determined utilising a second objective function. For example, the values of the initial configuration parameters may have been determined offline by applying an optimization process to the second objective function. The second objective function may be structured similarly to the first objective function, but may be different in some way. The application of an optimization process to the second objective function may be formulated differently to the application of an optimization process to the first objective function with respect to any of the components of the problem (objective function, parameters, constraints, optimization process applied etc.).

In some examples, the initial values may be obtained as an entry from a search space information (e.g. R in FIG. 1). The search space information may have been obtained by applying the optimization process to a second objective function (e.g. during the offline optimization). It will be appreciated that each entry of the search space information R may comprise a respective plurality of sets of initial values for initial configuration parameters of the plurality of functions.

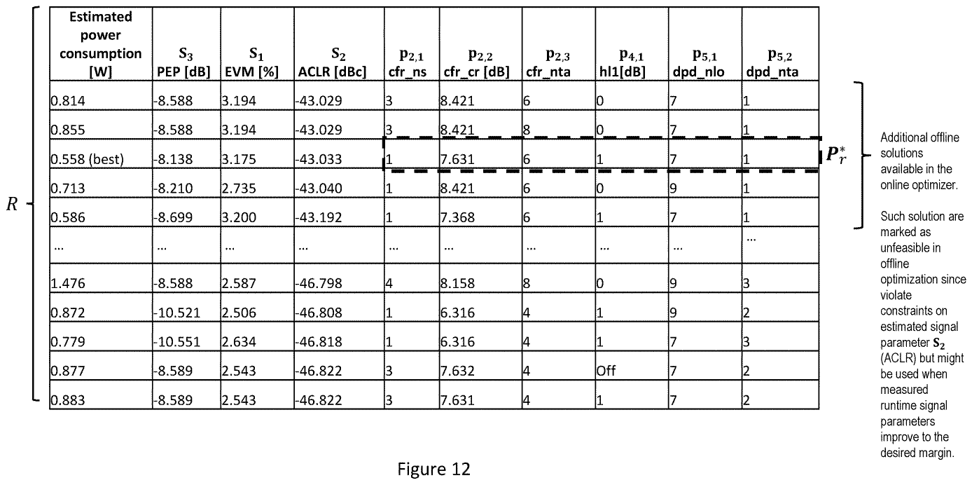

For example, in the case of grid-search optimization procedure, the online optimizer can receive the complete table including all the solutions explored by the offline optimizer (see FIG. 12) including, e.g., the solutions that were excluded in the offline optimization since not satisfying the constraints.

Typical examples of configuration parameters that may be optimized offline (and may therefore be examples of initial configuration parameters) are, e.g.: the nonlinear order of a digital pre-distortion (DPD) model, a number of stages of CFR algorithms, a threshold of the hard-limiter, etc.

Examples of configuration parameters that may be optimized online are: the coefficients of the DPD model, the tap configuration of the DPD model, the threshold of the hard-limiter, etc.

The values of the initial configuration parameters may be utilised as reference of fallback values to guide the optimization process of step 201.

When performing the method of FIG. 2 online, the method may also further comprise receiving one or more feedback signals (e.g. s₁[n], . . . , S_{N}_{_{F}}[n]) where NF comprises an integer value. The feedback signals may be utilised to determine the set of signal parameters.

In step 202 the method may optionally comprise initiating configuration of the DFE with the first values for the plurality of sets of first configuration parameters. Step 202 may for example comprise configuring the DFE with the first values by transmitting the values for the plurality of sets of first configuration parameters to the DFE. Alternatively, the values may be transmitted to some other node or functional block which may then implement update to the configuration parameters of the DFE.

In some examples, where the online optimizer receives the search space information R, in performing step 201, the online optimizer 301b may periodically acquire the signals s₁[n], . . . , S_{N}[n] and may evaluate the margins on the set of the constraints in (1) based on signal parameters S. It will be appreciated that the same constraints as given for the offline optimization may be used.

The online optimizer 301b may then utilise the search space information R provided by the offline optimizer 301 a (an example of R in tabular form can be found in FIG. 12), to decide which parameters p_{n,m} to adapt in the online optimization. This decision may be based on arbitrary logic, e.g., the increased or reduced margin of some of the signal parameters (e.g., ACLR) on the specific constraints compared to the offline optimization. The scope of such a change can be, for example, to exploit the margin to decrease a specific online objective function (e.g., energy consumption), or to re-establish sufficient margin from the specific constraints while minimizing the cost function increase. Such an optimization may be performed based on arbitrary constrained minimization or optimization strategy (which, as previously mentioned may be the same, or different to the offline optimization).

For example, step 201 may comprise determining a value of the first objective function (e.g. the online optimization) for an entry (e.g. each entry) of the search space information.

It will be appreciated that the output of the first objective function (online) may be different to the outputs of the second objective function (offline). For example, the functions may be structured slightly differently, and/or the simulations of the AFE and/or DFE utilised during the offline optimization may not be entirely accurate. It will therefore be appreciated that there may be some entries of the search space information that were considered infeasible during the offline optimization (e.g. as they were considered to violate one or more of the constraints), that may not be considered infeasible during the online optimization.

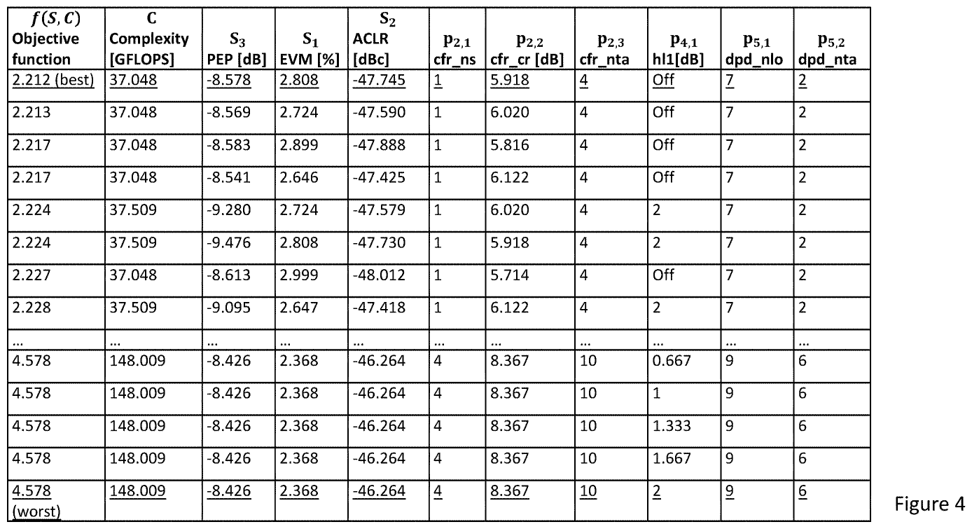

In the example of FIG. 4 therefore, the first 5 entries may be considered infeasible as they do not meet the constraint that S₂ (ACLR)<−46 dBc. However, during the online optimization, the same parameters settings for these entries may result in online values for S₂ (ACLR) that do meet this constraint.

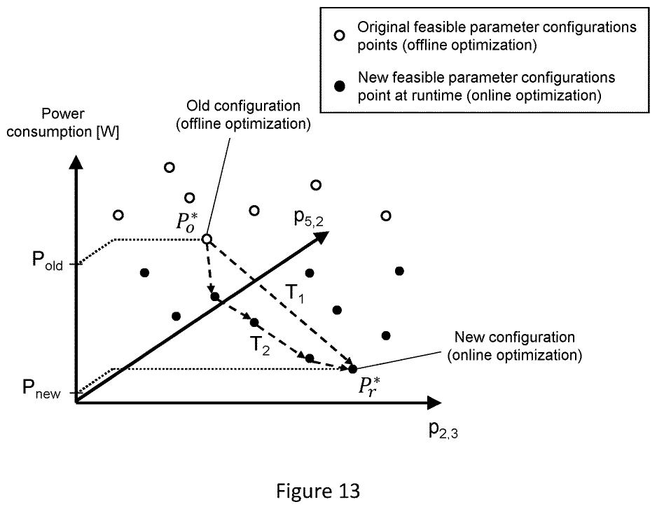

FIG. 13 is a graph illustrating an example of the provides an example of the values of the first objective function for the entries of the search space information R. In this example, the empty dots represent entries of the offline optimization that were considered feasible during the offline phase (e.g. the value of the second objective function did not violate any constraints). The solid dots represent entries of the online optimization that were not considered feasible during the offline phase (e.g. they violated one or more constraints).

In this example therefore, the entry P₀* may have been considered the best feasible option during the offline optimization, as it is feasible option associated with the lowest cost value for the power consumption.

An online optimization procedure (grid-search) is run over the set of entries R including the entries marked as unfeasible in FIG. 12. The optimization is performed with respect to the parameter set P_{R}, which is a subset of the parameter set Pₒ that was subject to the offline optimization. For representation purposes, FIG. 13 shows the optimization of the selected online cost (estimated power consumption) over a limited cut (parameters p_{2,3} and p_{5,2}) of the parameter space, while the optimization is operated over the entire Pₒ parameter space (6-dimensional in the example). The output of the online optimization is a new parameter vector P*ᵣ as during the online optimization, the runtime signal parameter S₂ (ACLR) for the point P*ᵣ met the above constraint.

In some examples, step 202 may then comprise utilising a directed acyclic graph (DAG) connecting a best feasible entry from the search space information (e.g. P*₀) with the values for the plurality of sets of first configuration parameters (e.g. P*ᵣ) determined by applying optimization process to progressively adjust the configuration of the DFE.

In other words, once

$${P}_{r}^{*}$$

has been determined, the

$${P}_{o}^{*} to {P}_{r}^{*}$$

parameters may be programmed in the DFE either progressively, i.e., following an arbitrary trajectory in the parameter space (see trajectory T₂ in FIG. 13), or directly (see trajectory T₁ in FIG. 13). A measurement process assessing system response e.g., via the signal parameters S, can be operated at each step of the trajectory to track system response and re-asses the margin of the signal parameters over constraints and feasibility region. It will be appreciated that the online optimization may be iterated with arbitrary timing.

An example of a process for determining a trajectory in the parameter space is described below.

In general, any arbitrary directed acyclic graph (DAG) may be utilised

$${P}_{o}^{*} to {P}_{r}^{*}$$

where the updated feasible set of points represent the vertexes of the DAGs.

The direct trajectory T₁ in FIG. 13 represents the most straightforward selection (1-vertex DAG). Nonetheless, it might be convenient to guide the settings via gradual selection of parameters to allow step-by-step tracking of system response, which can be done by choosing a longer trajectory. Below an example on how to select the trajectory:
i. Select a set P_{g} of parameter points in the form p_{g}=[P_{g,1}, . . . . P_{g,M}] such that each of the parameter points p_{g} is contained within a specific region of the parameter space. For example, the region can be the one including all the points that satisfy

$${p}_{o , i}^{*} \leq {p}_{g , i} \leq {p}_{r , i}^{*} if {p}_{o , i}^{*} \leq {p}_{r , i}^{*} \qquad ( 1 a )$$

$${p}_{r , i}^{*} \leq {p}_{g , i} \leq {p}_{o , i}^{*} if {p}_{o , i}^{*} > {p}_{r , i}^{*} \qquad ( 1 b )$$

for 1≤i≤M, which is the volume delimited by an hyperrectangle in the M-dimensional parameter space.
Other selections of the search region are also possible to limit or widen the range of the parameter-space trajectory.
ii. Given an arbitrary number of steps Nₛ find the shortest Nₛ-edges DAG computed over the set P_{g} connecting

$${P}_{o}^{*} to {P}_{r}^{*}$$

such that for each parameter p_{g,i} (with 1≤i≤M) one of the following is verified at each parameter update step nₛ:

P_{g,i}(nₛ)−P_{g,i}(nₛ−1)≥0, for 1≤nₛ≤Nₛ (2a)

or

P_{g,i}(nₛ)−P_{g,i}(nₛ−1)≤0, for 1≤nₛ≤Nₛ (2b)
where the initial coefficients P_{g,i}(0) can be initialized to 0 for convenience and the parameter Nₛ can be in practice used to tune the step size of the transition. Please note that other constraints on the selection of the trajectory can be selected other than (2a) and (2b), allowing for example a wider parameter swing, or constraints on some of the signal parameters S associated with each point (e.g., ACLR).
iii. Follow the trajectory and re-evaluate signal parameters S at each step to track system response and re-asses margin of signal parameters over constraints and feasibility region. The process can either continue until

$${P}_{r}^{*}$$

is reached or stop in an intermediate point if the measured signal parameters S show a contraction of the feasible region (e.g.,

$${P}_{r}^{*}$$

or next points in the trajectory are no longer in the feasible region).
With reference to FIG. 13 a selection of selection of Nₛ=1 leads to trajectory T₁, which corresponds to a direct selection of P*ᵣ parameters, while a selection of Nₛ=4 can lead to a trajectory like T₂. Please note that T₂ represents a case where (2a-2b) are satisfied, which can be seen from parameter p_{2,3} increasing at each step (2a), and P_{5,2} remaining constant (2a-2b).

In some examples, as described above, the method of FIG. 2 may by performed offline (e.g. by the offline optimizer 301a). In these examples, the method of FIG. 2 may further comprise receiving a data set, M, comprising one or more of: a set of measured signals (sₙ), a set of online signal parameters Sₒ derived from the set of measured signals (sₙ) and/or a model of the DFE. The method of FIG. 2 may then comprise updating the simulated DFE and/or the simulated AFE based on a data set, M. It will be appreciated that the set of measured signals (sₙ) comprises one or more of: the digital output signal y[n], a first feedback signal, s₁[n] derived from an output of the AFE, and a second feedback signal derived from any point inside the AFE. It will also be appreciated that the data set M may be received periodically, and the method of FIG. 2 may then comprise periodically updating the simulated DFE and/or the simulated AFE responsive to receiving the data set, M.

The method of FIG. 2 may comprise responsive to updating the simulated DFE and/or the simulated AFE, performing the steps of applying the optimization process and initiating configuration of the DFE with the plurality of sets of first configuration parameters.
providing the plurality of sets of first configuration parameters to an online optimizer, wherein the online optimizer is configured to perform the method of FIG. 2 online (e.g. as described above).

It will be appreciated that the offline and online optimization may be run together (e.g. at arbitrary timing). For example, the offline optimization may be performed at slower time periods e.g. receiving M every minute or second, updating the simulation and sending the online optimizer 301b a new search space information R. Whereas the online optimization may be run over faster time periods (e.g. millisecond or sub-millisecond), having received R, it may iterate a plurality of times before transmitting M to the offline optimizer and receiving a new R from the offline optimizer.

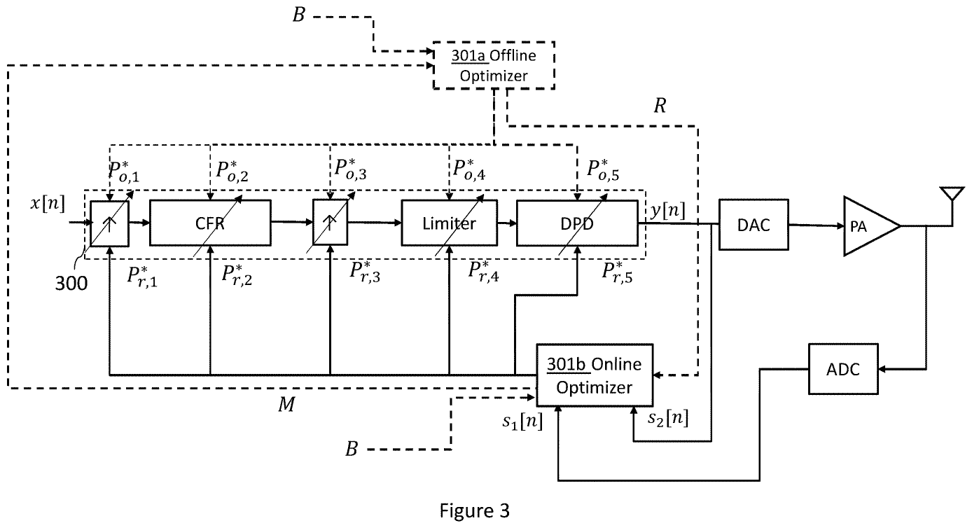

FIG. 3 illustrates an example of a DFE that may be configured by an optimizer 301 implementing the method of FIG. 2.

In particular, DFE 300 comprises a plurality of functions in the following cascaded blocks:
an up-sampling block (1) increasing the rate of the input signal x[n] to operate at desired rate for the CFR
a CFR block
a second up-sampling block (1) to further increase the sample-rate of the signal to allow a rate suitable for an optimal DPD operation
a digital hard-limiter block, to clip the extra signal peaks remaining after the CFR and generated by the up-sampler
a DPD block to operate digital predistortion.

In the example, all the blocks are parametrized, and the result of the offline optimizer 301a P*_{o,1}, . . . , P*_{o,5} may be used to determine values for initial configuration parameters of the DFE offline.

An example of the sets of initial configuration parameters in this specific case is (but not limited to):
for the up-samplers the sets P_{o,1} and P_{o,3} may comprise the following initial configuration parameters: an up-sampling ratio, a length of the finite-impulse response (FIR) filters used in the resampling process, a coefficients of the FIR filters.
For the CFR (e.g. a clip-and-filter-based CFR) the set P_{o,2} may comprise the following initial configuration parameters: a clipping threshold, a filter length, a number of stages, length and coefficients of the FIR filters used, internal down-/up-sampling ratios.
For the hard-limiter the set P_{o,4} may comprise the following initial configuration parameters: a threshold or clipping ratio used for the clipping, a state (active/bypassed) of the block.
For the DPD the set P₅ may comprise the following initial configuration parameters: a nonlinear order of the model, a memory depth of the nonlinear model, a type of nonlinear model, a configuration of memory taps in the model, an internal up-/down-sampling ratio.

The exemplary DFE chain in FIG. 3 operates with an online optimizer 301b as well as an offline optimizer 301a (although it will be appreciated these optimizers may be co-located) where the digital feedback signals $1 [n] and s₂[n] are used to generate the set of signal parameters S=[S₁, S₂, . . . . S_{L}], for example, comprising signal parameters such as EVM, ACLR, PEP, RMS power which can be used in both the first objective function and, optionally, one or more constraints.

In the following example, results of a proposed offline optimization of DFE of FIG. 3 are given. In this example, only some of the initial configuration parameters listed above are selected for optimization. As mentioned above, when the method of FIG. 2 is performed offline, the first configuration parameters comprise initial configuration parameters.

The sets of initial configuration parameters for use in the optimization in this example are as follows:
P_{o,2}={p_{2,1}, p_{2,2}, p_{2,3}} are the tuneable parameters of the clip-and-filter CFR stage (see for example, S Wang et al.)
   p_{2,1}, is the number of internal CFR stages (named cfr_ns in FIG. 4)
   p_{2,2}, is the clipping ratio of the CFR in dB (named cfr_cr in FIG. 4).
   p_{2,3}, is number of coefficients for the filters used internally in the CFR (named cfr_nta in FIG. 4).
P_{o,4}={p_{4,1}} is the parameter of the hard-limiter stage
   p_{4,1}, is the relative clip ratio in dB of the limiter with respect to the CFR (named hl1 in FIG. 4); the parameter can also have the state “Off”, which means that the stage is not present.
P_{o,5}={p_{5,1}, p_{5,2}} are the parameters of the DPD stage, which assumes a direct implementation of memory-polynomial model (see for example, S Wang et al.)
   p_{5,1}, is the maximum nonlinearity order included in the DPD model (named dpd_nlo in FIG. 4)
   p_{5,2}, is the number of taps in the DPD model (named dpd_nta in FIG. 4)
      The first objective function in this example composed as:

$$f ( S , C ) = \frac{b}{{EVM}_{C}} EVM + \frac{c}{{ACLR}_{C}} ACLR + \frac{a}{{C}_{REF}} ( {C}_{CFR} + {C}_{HL} + {C}_{DPD} ) +$$

$$Subject to : \{ \begin{matrix}EVM \leq {EVM}_{C} \\ ACLR \leq {ACLR}_{C} \\ PEP \leq {PEP}_{C} \\ {P}_{RMS , C 1} \leq {P}_{RMS} ( {P}_{1} , … {P}_{5} ) \leq {P}_{RMS , C 2}\end{matrix}$$

with
S(P₁, . . . , P₅)=[ACLR, EVM, PEP, P_{RMS}] is a vector of signal parameters where ACLR and EVM are modelled in a simulated DFE/AFE at the PA output (s₁[n] feedback signal from the simulated DFE/AFE), and PEP (peak-envelope power) and P_{RMS} (RMS power) are modelled in the simulated DFE/AFE at the PA input (s₂ [n] feedback signal from the simulated DFE/AFE). The signal parameters ACLR, EVM, PEP, and P_{RMS} are all dependent on the parameters P₁ to P₅.
C_{CFR}, C_{HL}, and C_{DPD} are computational costs in terms of FLOPS of the CFR, hard-limiter, and DPD blocks, respectively; they are estimated based on knowledge of the specific algorithms. C_{CFR}=C_{CFR}(P₂), C_{HL}=C_{HL}(P₄), C_{DPD}=C_{DPD}(P₅),
C_{REF} is an arbitrary normalization constant for the computational cost term.
a, b, c, are weighting parameters used to adjust the importance of the computational cost, EVM, and ACLR in the optimization, respectively within the first objective function.
ACLR_{C}, EVM_{C}, PEP_{C}, P_{RMS,C1}, P_{RMS,C2} are limit values for
   the ACLR, EVM measured at PA output
   the PEP and RMS power measured at PA input.

In this example, the optimization has been performed with a grid-search approach while basing the calculation of signal parameters S(P₁, . . . , P₅)=[ACLR(P₁, . . . , P₅), EVM(P₁, . . . , P₅), PEP(P₁, . . . . P₅), P_{RMS}(P₁, . . . . P₅)] on a simulated DFE chain and simulated AFE, which in this example includes a PA modelled with a memory polynomial.

The calculation of C_{CFR}, C_{HL}, and C_{DPD} computational cost in terms of FLOPS, is done using closed-form expressions related to the implemented algorithms (clip and filter for CFR, memory polynomial for DPD).

The results of the optimization are illustrated in FIG. 4, which shows the outcome of the optimization with an objective function calculated with a=1, b=1, c=1 (valuing equally low cost, low EVM, and low ACLR) and with C_{REF}=40 Giga FLOPS (GFLOPS). The constraints on output signal are set based on selected requirements from 3GPP TS 38.104 version 15.14.0, such that EVM_{C}=3.5%, ACLR_{C}=−46 dBc. The constraints on input signal are set so that PEP_{C}=−8 dB, P_{RMS,C1}=−18.9 dB, and P_{RMS,C2}=−19.1 dB.

It is shown that required optimization achieves the desired scope (e.g. in the top line of the table of FIG. 4) of producing a solution that is a reasonable compromise of complexity, ACLR and EVM performance over the feasible solution space (that is, the solutions satisfying the constraints). Although the results for RMS power, P_{RMS},are not shown in the table, the optimized solution also satisfies the RMS constraints (P_{RMS,C1}; P_{RMS,C2}). It should be noted that different selection of a, b, c parameters would have produced different rankings of the feasible solutions. E.g., a=0, b=1, c=0 would have minimized the EVM, while ignoring the ACLR and complexity metrics.

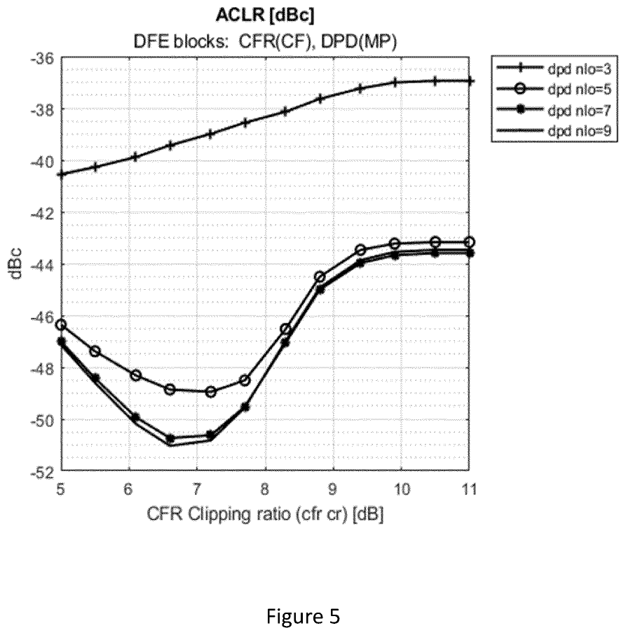

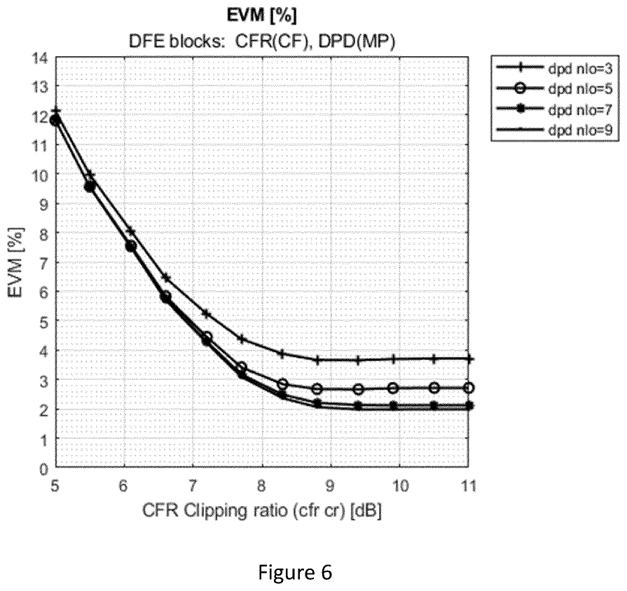

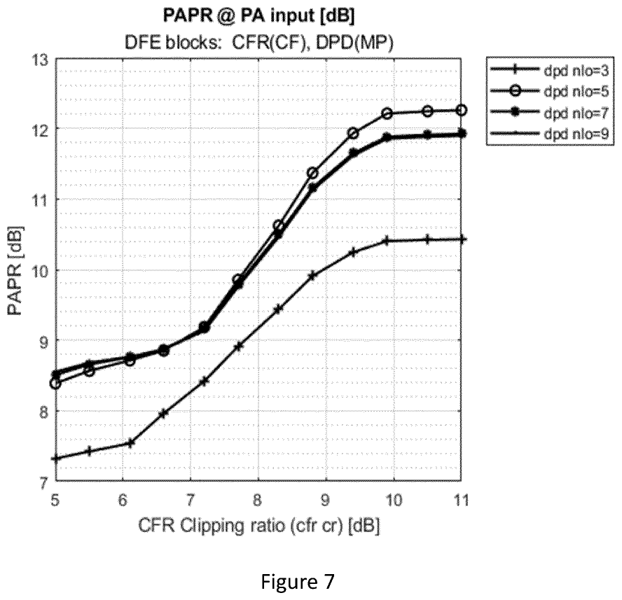

In FIG. 5, FIG. 6, and FIG. 7 some signal parameters for the example illustrated in FIG. 3 at PA output (EVM, ACLR) and at PA input (PAPR) with respect to a limited number of P-parameters, i.e., the clipping ratio of CFR (p_{2,2}) and the maximum nonlinear order of the DPD model (p_{5,1}) are shown. It will be appreciated that the plotted curves are valid only when the other four P-parameters are fixed to p_{2,1}=4, p_{2,3}=8, p_{4,1}=‘Off’, p_{5,2}=7.

A manual block-by-block optimization would require a manually sweep through all (or a sensible subset of) the possible combinations of parameters per each block sequentially, which is already a time-consuming operation. Furthermore, this manual sweep is likely to lead to a sub-optimal configuration of parameters as the interconnections between consecutive blocks are not taken into account. For example, an optimization of the CFR blocks will lock the parameter setting for the CFR parameters, (that is p_{2,1}, p_{2,2}, and p_{2,3}) and optimize the hard-limiter parameter (that is p_{4,1}) only given the specific parameter setting for the CFR, and so on sequentially for the remaining blocks in the chain, that is that is p_{2,1}, p_{2,2}, and p_{2,3} for the DPD. So, even in this example with reduced complexity, the manual sweep will lead to overlooking a large portion of the parameter space. While the impact of this is difficult to estimate (depends on the specific practice for manual parameter setting) it will generally lead to sub-optimal solutions and to a much more cumbersome optimization process than the embodiments proposed here.

FIG. 5 illustrates ACLR at the PA output (of FIG. 3) when varying the nonlinear order of the DPD and clipping ratio of CFR block.

FIG. 6 illustrates the EVM at PA output (of FIG. 3) when varying nonlinear order of the DPD and clipping ratio of CFR block.

FIG. 7 illustrates PAPR at PA input (of FIG. 3) when varying nonlinear order of the DPD and clipping ratio of CFR block.

It can be seen from FIGS. 5 to 7 that in a manual optimization is it practical to sweep the parameters one or two at a time (e.g., clipping-ratio and nonlinear order) but is impractical to understand what happens to the signal parameters when e.g., 6 parameters are jointly varied. Therefore, a manual optimization may lead to miss a large part of the parameter space.

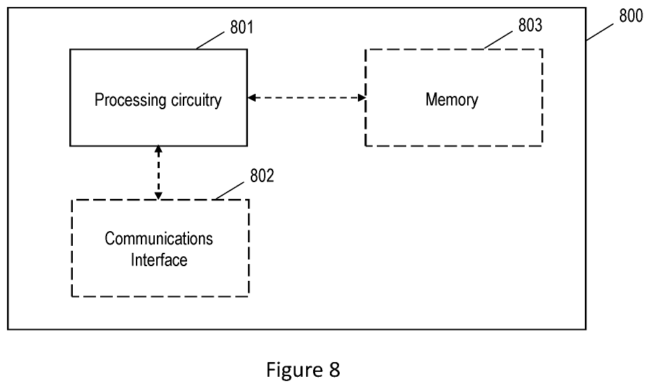

FIG. 8 illustrates an optimizer 800 comprising processing circuitry (or logic) 801. The processing circuitry 801 controls the operation of the optimizer 800 and can implement the method described herein in relation to an optimizer 800. The processing circuitry 801 can comprise one or more processors, processing units, multi-core processors or modules that are configured or programmed to control the optimizer 800 in the manner described herein. In particular implementations, the processing circuitry 801 can comprise a plurality of software and/or hardware modules that are each configured to perform, or are for performing, individual or multiple steps of the method described herein in relation to the optimizer 800. It will be appreciated that the optimizer 800 may comprise one or more virtual machines running different software and/or processes. The optimizer 800 may therefore comprise, or be implemented in or as one or more servers, switches and/or storage devices and/or may comprise cloud computing infrastructure that runs the software and/or processes.

Optionally, the optimizer 800 may comprise a memory 803. In some embodiments, the memory 803 of the optimizer 800 can be configured to store instructions (e.g. program code) executable by the processing circuitry 801 of the optimizer 800 whereby the apparatus is operable to perform the method as described above (e.g. in relation to FIG. 2).

Alternatively or in addition, the memory 803 of the optimizer 800, can be configured to store any requests, resources, information, data, signals, or similar that are described herein. The processing circuitry 801 of the optimizer 800 may be configured to control the memory 803 of the optimizer 800 to store any requests, resources, information, data, signals, or similar that are described herein

In some embodiments, the optimizer 800 may optionally comprise a communications interface 802. The communications interface 802 of the optimizer 800 can be for use in communicating with other nodes, such as other virtual nodes. For example, the communications interface 802 of the optimizer 800 can be configured to transmit to and/or receive from other nodes requests, resources, information, data, signals, or similar. The processing circuitry 801 of optimizer 800 may be configured to control the communications interface 802 of the optimizer 800 to transmit to and/or receive from other nodes requests, resources, information, data, signals, or similar. The communications interface 802 can use any suitable communication technology.

The optimizer 800 may be configured operate in the manner described herein in respect of an optimizer.

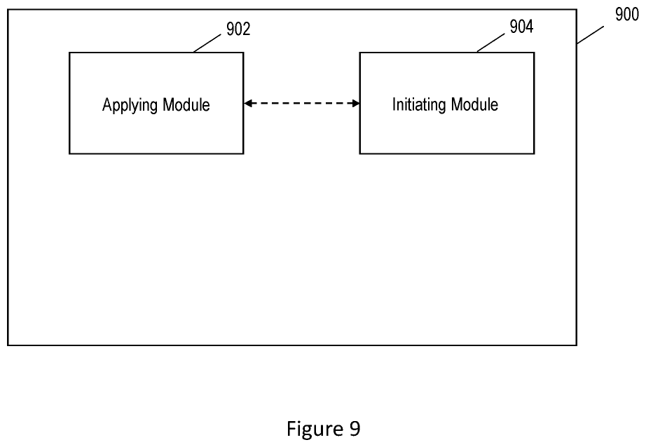

FIG. 9 is a block diagram illustrating an optimizer 900 according to some embodiments. The optimizer is for a digital front end, DFE, wherein the DFE is configured to perform a plurality of functions, to generate a digital output signal, y[n], from a digital input signal, x[n], and wherein the method is for determining values P₁* . . . . P_{M}′ for a respective plurality of sets, P₁ . . . . P_{N}, of first configuration parameters, for the plurality of functions, wherein the digital output signal y[n] is for input into an analog front end, AFE. The optimizer 900 comprises an applying module 902 configured to apply an optimization process to a first objective function to determine values for the plurality of set of first configuration parameters, wherein the first objective function comprises a first component derived from a set, S, of signal parameters, representative of the digital output signal y[n] and/or of signals measured at arbitrary points in the AFE, wherein the set of signal parameters is dependent on the plurality of sets, P₁ . . . . P_{M}, of first configuration parameters. The optimizer 900 comprises a initiating module 904 configured to initiate configuration of the DFE with the plurality of sets of first configuration parameters. The optimizer 900 may operate in the manner described herein in respect of an optimizer.

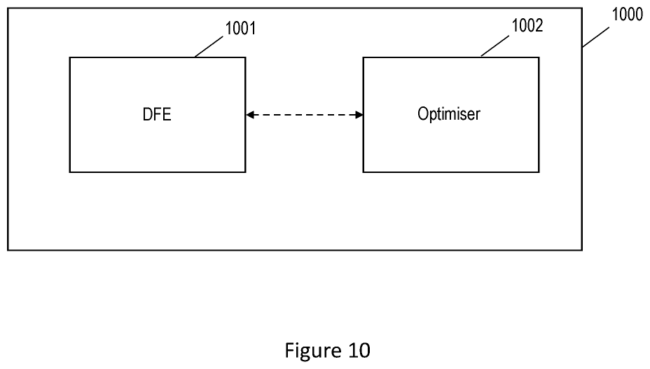

FIG. 10 illustrates a base station 1000 comprising a DFE 1001. The base station 1000 further comprises an optimizer 1002. The optimizer 1002 may be configured as described with reference to FIG. 8 or 9, or may be configured to perform the method as described with reference to FIG. 2.

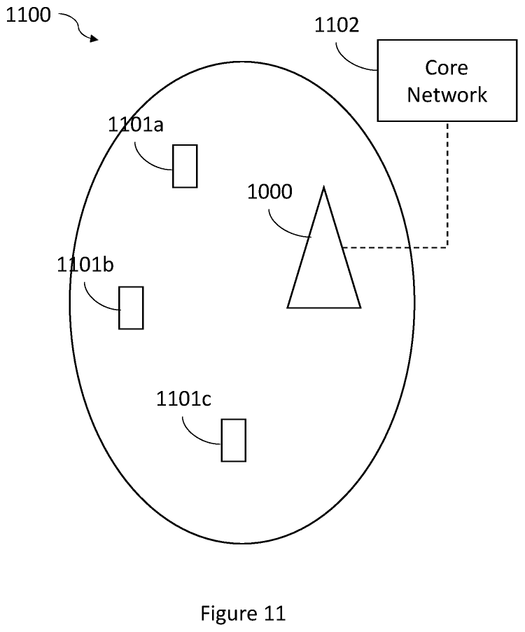

FIG. 11 illustrates a communications network 1100 comprising a base station 1000, a plurality of UEs 1101a to 1101c and a core network 1102. The base station 1000 may be configured as described with reference to FIG. 10.

There is also provided a computer program comprising instructions which, when executed on a least one processor (such as the processor 701 of the optimizer 700 described earlier), cause the processor to carry out at least part of the method(s) described herein. According to some embodiments there is provided a carrier containing the computer program. In some embodiments, the carrier can be any one of an electronic signal, an optical signal, an electromagnetic signal, an electrical signal, a radio signal, a microwave signal, or a computer-readable medium. There is also provided a (for example, tangible and/or non-transient) computer-readable medium comprising instructions which, when executed by at least one processor, cause the at least one processor to perform at least part of the method(s) described herein.

Advantages of embodiments described herein may be mapped to the limitations of prior art expressed in the background and summary sections.

Embodiments described herein ensure that the optimization of all, or a relevant part, of the DFE blocks is done jointly, therefore exploiting the interconnections among the blocks to achieve an improved balance among performance (e.g., signal quality, emissions suppression) and complexity of the processes.

While existing literature principally focuses on proposing novel processes for CFR and DPD which can work in synergy, or merge the two blocks, the proposed embodiments may be used with arbitrary processes implemented in the CFR and DPD stages, as long as they can be parametrized.

Embodiments described herein may be used for multiple scopes: 1) aiding the design phase (offline optimization mode), 2) reconfiguration of blocks (offline optimization mode), and 3) online adaptation of DFE blocks (runtime optimization mode), while exploiting the advantages of joint optimization of multiple blocks in all the mentioned cases.

It should be noted that the above-mentioned embodiments illustrate rather than limit the invention, and that those skilled in the art will be able to design many alternative embodiments without departing from the scope of the appended claims. The word “comprising” does not exclude the presence of elements or steps other than those listed in a claim, “a” or “an” does not exclude a plurality, and a single processor or other unit may fulfil the functions of several units recited in the claims. Any reference signs in the claims shall not be construed so as to limit their scope.

1-32. (canceled)

33. A method performed by an optimizer for a digital front end, DFE, the DFE being configured to perform a plurality of functions, to generate a digital output signal, y[n], from a digital input signal, x[n], the digital output signal y[n] being for input into an analog front end, AFE, the method comprising:
applying an optimization process to a first objective function to determine first values P1* . . . . PM* for a respective plurality of sets of first configuration parameters, P1 . . . . PM, for the plurality of functions, the first objective function comprising a first component derived from a set, S, of signal parameters representative of one or both of the digital output signal y[n] and of one or more analog signals measured at one or both of a point within and at an output of the AFE, the set of signal parameters being dependent on the plurality of sets, P1 . . . . PM, of first configuration parameters; and
configuring the DFE with the first values of the plurality of sets of first configuration parameters.

34. The method of claim 33, wherein each signal parameter, S1 . . . . SL¬, in the set, S, of signal parameters is dependent on the plurality of sets, P1 . . . . PM, of first configuration parameters.

35. The method of claim 33, wherein:
the first objective function comprises a second component derived from respective costs associated with the plurality of functions;
the respective costs comprise a respective power consumption cost; or
the respective costs comprise respective computational costs C1-CM.

36. The method of claim 35, wherein the computational costs, C1 . . . . CM, are dependent on the plurality of sets of first configuration parameters; and
wherein each of the computational costs is dependent on the respective set of first configuration parameters for the associated function.

37. The method of claim 33, wherein:
the first component is further derived from a set, B, of baseband parameters; and
the set B comprises one or more of: a number of baseband carriers, one or more frequencies of baseband carriers, one or more bandwidths of baseband signals, one or more modulation and coding schemes of carriers and a power of one or more carriers.

38. The method of claim 33, wherein applying the optimization process comprises minimising the first objective function.

39. The method as claimed in claim 33, wherein the optimization process comprises one or more of:
a grid-search process over possible values for the respective sets of first configuration parameters;
mixed integer, linear or quadratic programming; and
machine learning.

40. The method of claim 33, wherein:
the optimization process is subject to one or more constraints; and
the one or more constraints comprise one or more limits on values of the set of signal parameters.

41. The method of claim 40, wherein:
the first objective function comprises a second component derived from respective costs associated with the plurality of functions; and
the one or more constraints comprise one or more limits on values of the costs.

42. The method of claim 33, wherein:
the method is performed offline; and
the set of signal parameters, S, are determined utilising one or more of a simulated DFE and a simulated AFE.

43. The method of claim 42, further comprising:
receiving a data set, M, comprising one or more of: a set of measured signals (s_n), a set of online signal parameters So derived from one or both of the set of measured signals (s_n) and a model of the DFE; and
updating the one or both of the simulated DFE and the simulated AFE based on a data set, M.

44. The method of claim 43, wherein the set of measured signals (Sₙ) comprises one or more of: the digital output signal y[n], one or more first feedback signals, s₁[n] derived from an output of the AFE, and a second feedback signal derived from any point inside or at the output of the AFE.

45. The method of claim 44, further comprising receiving the data set periodically, and periodically updating the one or both of the simulated DFE and the simulated AFE responsive to receiving the data set, M.

46. The method of claim 43, further comprising:
responsive to updating the one or both of the simulated DFE and the simulated AFE, repeating the applying the optimization process and configuring the DFE with the first values of the plurality of sets of first configuration parameters.

47. The method of claim 33, further comprising providing the plurality of sets of first configuration parameters to an online optimizer, wherein the online optimizer is configured to perform the applying and configuring.

48. The method of claim 33, wherein the method is performed online.

49. The method of claim 48 wherein the set of signal parameters are determined from one or more of: the digital output signal y[n], a first feedback signal, s1[n] derived from an output of the AFE, and a second feedback signal derived from any point inside the AFE.

50. The method of claim 33, wherein the plurality of functions comprises one or more of:
crest-factor reduction, digital hard-limiting, digital pre-distortion, up-sampling or down-sampling, and digital filtering.

51. The method of claim 33, wherein the set of signal parameters comprises one or more of:
error vector magnitude, EVM, adjacent channel leakage ratio, ACLR, peak-envelope power, PEP, and root mean squared, RMS, power.

52. An optimizer for a digital front end, DFE, the optimizer configured to perform a plurality of functions, to generate a digital output signal, y[n], from a digital input signal, x[n], the digital output signal y[n] being for input into an analog front end, AFE, by being further configured to:
apply an optimization process to a first objective function to determine first values P1* . . . . PM* for a respective plurality of sets of first configuration parameters, P1 . . . . PM, for the plurality of functions, the first objective function comprising a first component derived from a set, S, of signal parameters representative of one or both of the digital output signal y[n] and of one or more analog signals measured at one or both of a point within and at an output of the AFE, the set of signal parameters being dependent on the plurality of sets, P1 . . . . PM, of first configuration parameters; and
configure the DFE with the first values of the plurality of sets of first configuration parameters.

53. The system optimizer of claim 52, wherein the system optimizer is comprised in a base station.

54. A storage medium comprising a computer program comprising instructions which, when executed on at least one processor, cause the at least one processor to perform a method for a digital front end, DFE, the DFE being configured to perform a plurality of functions, to generate a digital output signal, y[n], from a digital input signal, x[n], the digital output signal y[n] being for input into an analog front end, AFE, the method comprising:
applying an optimization process to a first objective function to determine first values P1* . . . . PM* for a respective plurality of sets of first configuration parameters, P1 . . . . PM, for the plurality of functions, the first objective function comprising a first component derived from a set, S, of signal parameters representative of one or both of the digital output signal y[n] and of one or more analog signals measured at one or both of a point within and at an output of the AFE, the set of signal parameters being dependent on the plurality of sets, P1 . . . . PM, of first configuration parameters; and
configuring the DFE with the first values of the plurality of sets of first configuration parameters.
